(19) United States
(12) Patent Application Publication
(10) Pub. No.: US 2009/0243669 A1
(43) Pub. Date: Oct. 1, 2009

(54) POWER-ON RESET CIRCUIT

(75) Inventors: JEN-SHENG TSAI, Tu-Cheng (TW); JI YANG, Shenzhen City (CN); YING LUO, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/237,223

(22) Filed: Sep. 24, 2008

(30) Foreign Application Priority Data
Mar. 28, 2008 (CN) 200810300761.3

(51) Int. Cl. H03L 7/00

(52) U.S. Cl. 327/143

(57) ABSTRACT

A power-on reset circuit includes a voltage-dividing circuit, a first switch and a second switch. The voltage-dividing circuit includes a first resistor and a second resistor connected in series. A first terminal of the voltage-dividing circuit is configured for connect to a power source, a second terminal of the voltage-dividing circuit is grounded. A first switch includes an input terminal, a control terminal, and an output terminal. The input terminal of the first switch is connected to the first terminal of the voltage-dividing circuit via the first resistor, and the output terminal of the first switch is grounded. A second switch includes an input terminal connected to the first terminal of the voltage-dividing circuit, a control terminal connected to the control terminal of the first switch, and an output terminal connected to a reset terminal of an electronic device.

### BACKGROUND

1. Field of the Invention

Embodiments of the present disclosure relate to reset circuits and, more particularly, to a power-on reset circuit.

2. Description of the Related Art

Electronic devices typically include a power-on reset circuit to restore the electronic devices to an initial status when the power applied to the electronic device is either initially turned on or turned off and then turned on. However, when a voltage of the power source drops for some other reasons, an unpredictable status of an electronic device may occur due to the low voltage. After normal voltage is restored, the electronic device may not be able to operate normally because internal signals caused by the previous low voltage state are out of the spec.

Accordingly, it is desired to provide a power-on reset circuit which can overcome the above-mentioned problems.

### BRIEF DESCRIPTION OF THE DRAWINGS

FIG. 1 is a schematic view of a power-on reset circuit according to a first embodiment.

FIG. 2 is a schematic view of a power-on reset circuit according to a second embodiment.

### DETAILED DESCRIPTION OF EMBODIMENTS

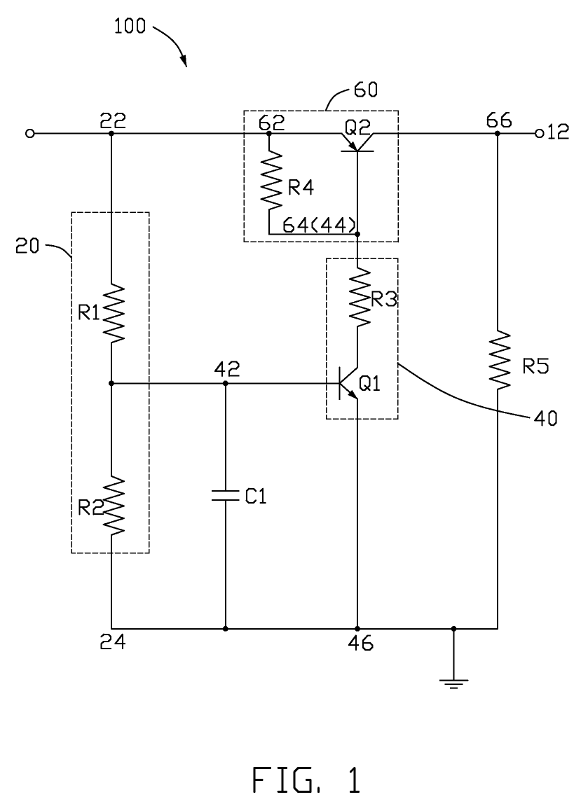

Referring to the FIG. 1, a power-on reset circuit 100 includes a voltage-dividing circuit 20, a first switch 40, and a second switch 60.

The voltage-dividing circuit 20 includes a first resistor R1 and a second resistor R2 connected in series. A first terminal 22 of the voltage-dividing circuit 20 is configured to connect to a power source and a second terminal 24 of the voltage-dividing circuit 20 is grounded. In one embodiment, the power source is a power source of a portable electronic device. A first terminal of the resistor R1 is connected to the first terminal 22 of the voltage-dividing circuit 20. A second terminal of the resistor R1 is connected to a first terminal of the second resistor R2. A second terminal of the second resistor R2 is connected to the second terminal 24 of the voltage-dividing circuit 20, so that the second terminal of the second resistor R2 is grounded.

The first switch 40 includes an input terminal 42, a control terminal 44 and an output terminal 46. The input terminal 42 of the first switch 40 is connected to the junction of the second terminal of the first resistor R1 and the first terminal of the second resistor R2, and the output terminal 46 of the first switch 40 is grounded.

In one embodiment, the first switch 40 includes a first transistor Q1 and a third resistor R3. The first transistor Q1 is an NPN-type transistor. The base of the first transistor Q1 is connected to the junction of the second terminal of the first resistor R1 and the first terminal of the second resistor R2. The collector of the first transistor Q1 is connected to a first terminal of the third resistor R3. The emitter of the first transistor Q1 is grounded. The third resistor R3 is a current-limiting resistor configured for limiting current flowing through the first transistor Q1.

The second switch 60 includes an input terminal 62, a control terminal 64, and an output terminal 66. The input terminal 62 of the second switch 60 is connected to the first terminal 22 of the voltage-dividing circuit 20. The control terminal 64 of the second switch 60 is connected to the control terminal 44 of the first switch. In other words, the control terminal 64 of the second switch 60 is connected to a second terminal of the third resistor R3. The output terminal 66 of the second switch 60 is connected to a reset terminal 1 2 of the portable electronic device.

In one embodiment, the second switch 60 includes a second transistor Q2 and a fourth resistor R4. The second transistor Q2 is a PNP-type transistor. The base of the second transistor Q2 and a first terminal of the fourth resistor R4 are both connected to the second terminal of the third resistor R3. A second terminal of the fourth resistor R4 and the emitter of the second transistor Q2 are both connected to the first terminal of the first resistor R1. The collector of the second transistor Q2 is connected to the reset terminal 1 2. In one embodiment, the reset terminal 12 is connected to a pin of one or more chips that may be present in the portable electronic device, to reset the chips.

In one embodiment, when the voltage of the reset terminal 12 is high, the portable electronic device will operate normally. When the voltage of the reset terminal 12 goes low, the one or more chips with the pin will reset to an initial condition. In other words, the portable electronic device will reset to an initial condition.

When the power source is turned on, power supplied may be initially unstable. Accordingly, the electronic device could operate in an unpredictable status, and the electronic device may be damaged. In order to prevent the electronic device from operating in an unpredictable status during the initial instability, a delay circuit is needed to delay bringing the electronic device online a predetermined amount of time after the power source is turned on.

In one embodiment, the power-on reset circuit 100 further includes a capacitor C1. The capacitor C1 functions as a delay circuit and is configured for providing a predetermined delay time. A first terminal of the capacitor C1 and the base of the first transistor Q1 are connected to the junction of the second terminal of the first resistor R1 and the second terminal of the second resistor R2, and a second terminal of the capacitor C1 is grounded.

The one or more chips with the pin connected to the reset terminal 12 has a predetermined voltage associated with it. When the voltage of the power source is higher than the predetermined voltage, the voltage of the power source is applied to the capacitor C1 via the first resistor R1 to charge the capacitor C1 for the predetermined time. The predetermined time of charging the capacitor C1 may vary depending on the particular resistor used for the first resistor R1, the second resistor R2, and the particular capacitance of the capacitor C1. The predetermined time can be determined according to the needs of users. After the predetermined time, the voltage of the capacitor C1 is higher than the voltage between the base and the emitter of the first transistor Q1. Therefore, the first transistor Q1 is turned on.

When the voltage of the power source is lower than the predetermined voltage, the capacitor C1 will discharge. If the voltage of the capacitor C1 is lower than the voltage between the base and the emitter of the first transistor Q1, the first transistor Q1 is turned off.

A pull down resistor may be used to prevent the portable electronic device from operating in an uncertain status. In one present embodiment, the power-on reset circuit 100 further includes a fifth resistor R5. The fifth resistor R5 is a pull down resistor. A first terminal of the fifth resistor R5 is connected to the collector of the second transistor Q2, and a second terminal of the fifth resistor R5 is grounded.

In operation, the power source charges the capacitor C1 for a predetermined time, via the first resistor R1 and the second resistor R2. After the predetermined time, the capacitor C1 is in a saturation condition, and the first transistor Q1 is turned on. As a result, the second transistor Q2 is turned on via the third resistor R3. The power-on reset circuit 100 provides the voltage of the power source to the reset terminal 12 after the predetermined time has elapsed, the voltage of the reset terminal 12 is high, and the portable electronic device will operate in a stable condition.

If the power source drops to the predetermined voltage, the voltage applied on the base of the first transistor Q1 will drop to cause the first transistor Q1 to turn off, causing the second transistor Q2 to be turned off. The voltage of the reset terminal 12 is low, and the portable electronic device will be initialized.

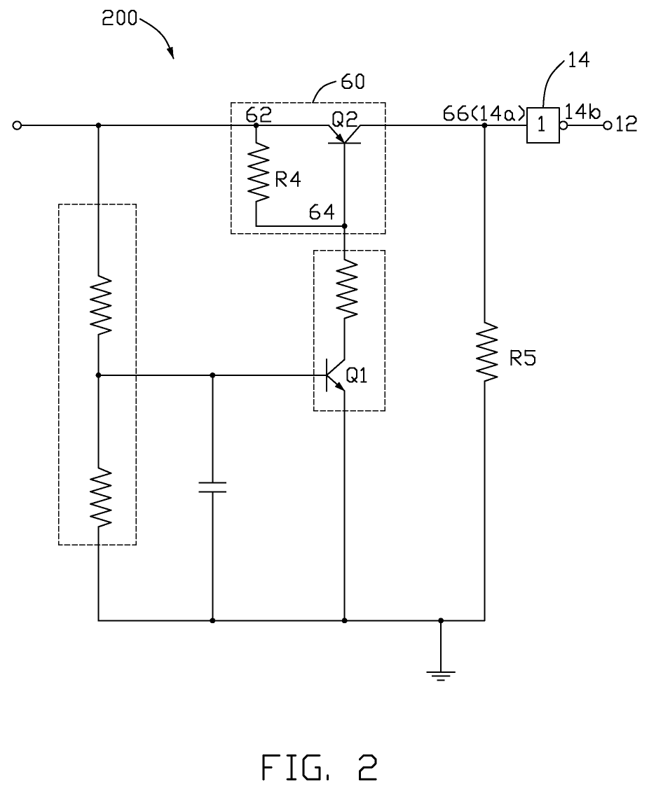

FIG. 2 is a schematic view of a power-on reset circuit 200 according to a second embodiment. In one embodiment, if a voltage of the reset terminal 12 is low, a chip connected to the reset terminal 12 via a pin is disabled, and the portable electronic device will operate normally. When the voltage of the reset terminal 12 is low, the one or more chips with the pin will restore to an initial condition thereof. In other words, the portable electronic device will restore to an initial condition.

The power-on reset circuit 200 is similar to the power-on reset circuit 100 except that the power-on reset circuit 200 further includes a reverser 14. The reverser 14 includes an input terminal 14a and an output terminal 14b. The input terminal 14a of the reverser 14 is connected to the output terminal 66 of the second switch 60. The output terminal 14b of the reverser 14 is connected to the reset terminal 12.

It may be appreciated if the second switch 60 includes a second transistor Q2, the input terminal 14a of the reverser 14 is connected to the junction of the collector of the second transistor Q2 and the first terminal of the fifth resistor R5, and the output terminal 14b of the reverser 14 is connected to the reset terminal 12.

If the voltage of the power source drops to the predetermined voltage, the voltage applied on the base of the first transistor Q1 will drop, causing the first transistor Q1 to be turned off. As a result, the second transistor Q2 is turned off. The voltage of the input terminal 14a of the reverser 14 is low, the voltage of the output terminal 14b is high, the voltage of the reset terminal 12 is high, and the portable electronic device will be initialized.

The power-on reset circuit 100, 200 can reset the electronic device to prevent the electronic devices from operating in an unpredictable status when the power source applied to the electronic devices or the voltage of the power source is too low. Advantageously, the power-on reset circuit 100, 200 can delay bringing the electronic device online the predetermined amount of time after the power source is turned on for making the electronic devices operate normally.

It is to be understood, however, that even though numerous characteristics and advantages of the embodiments have been set forth in the foregoing description, together with details of the structures and functions of the embodiments, the disclosure is illustrative only, and changes may be made in detail, especially in matters of arrangement of parts within the principles of the invention to the full extent indicated by the broad general meaning of the terms in which the appended claims are expressed.

What is claimed is:

1. A power-on reset circuit comprising:
a voltage-dividing circuit comprising a first resistor and a second resistor connected in series, a first terminal of the voltage-dividing circuit configured for connecting to a power source, a second terminal of the voltage-dividing circuit being grounded;
a first switch comprising an input terminal connected to the first terminal of the voltage-dividing circuit via the first resistor, a control terminal, and an output terminal being grounded;
a second switch comprising an input terminal connected to the first terminal of the voltage-dividing circuit, a control terminal connected to the control terminal of the first switch, and an output terminal connected to a reset terminal of an electronic device.

2. The power-on reset circuit of claim 1, wherein a first terminal of the first resistor is connected to the first terminal of the voltage-dividing circuit; a second terminal of the first resistor is connected to a first terminal of the second resistor; a second terminal of the second resistor is grounded.

3. The power-on reset circuit of claim 1, further comprising a fifth resistor, a first terminal of the fifth resistor is connected to the output terminal of the second switch; a second terminal of the fifth resistor is grounded.

4. The power-on reset circuit of claim 1, further comprising a reverser, wherein the reverser comprises an input terminal and an output terminal; the input terminal of the reverser is connected to the output terminal of the second switch; the output terminal of the reverser is connected to the reset terminal.

5. The power-on reset circuit of claim 1, wherein the first switch comprises a first transistor, the base of the first transistor is connected to the junction of a second terminal of the first resistor and a first terminal of the second resistor; the collector of the first transistor is connected to control terminal of the second switch; the emitter of the first transistor switch is grounded.

6. The power-on reset circuit of claim 5, wherein the first transistor is an NPN-type transistor.

7. The power-on reset circuit of claim 5, wherein the first switch further comprises a third resistor, the collector of the first transistor is connected to the control terminal of the second switch via the third resistor.

8. The power-on reset circuit of claim 5, further comprising a capacitor, wherein a first terminal of the capacitor and the base of the first transistor are connected to the first terminal of the voltage-dividing circuit via the first resistor; a second terminal of the capacitor is grounded.

9. The power-on reset circuit of claim 5, wherein the second switch comprises a second transistor and a fourth resistor, wherein the base of the second transistor and the collector of the first transistor are both connected to a first terminal of the fourth resistor; a second terminal of the fourth resistor and the emitter of the second transistor are both connected to the first terminal of the voltage-dividing circuit; the collector of the second transistor is connected to the reset terminal.

10. The power-on reset circuit of claim 9, wherein the first switch further comprises a third resistor; a first terminal of the third resistor is connected to the collector of the first transistor; a second terminal of the third resistor is connected to the junction of the first terminal of the fourth resistor and the base of the second transistor.

11. The power-on reset circuit of claim 1, wherein the second switch comprises a second transistor and a fourth resistor, wherein the base of the second transistor and a first terminal of the fourth resistor are both connected to the control terminal of the first switch; the emitter of the second transistor and a second terminal of the fourth resistor are both connected to the first terminal of the voltage-dividing circuit; the collector of the second transistor is connected to the reset terminal.

12. The power-on reset circuit of claim 1 I, wherein the second transistor is a PNP-type transistor.

13. The power-on reset circuit of claim 1 I, further comprising a reverser, wherein the reverser comprises an input terminal and an output terminal; the input terminal of the reverser is connected to the collector of the second transistor; the output terminal of the reverser is connected to the reset terminal.

14. The power-on reset circuit of claim 1 I, further comprising a fifth resistor; a first terminal of the fifth resistor is connected to the collector of the second transistor; a second terminal of the fifth resistor is grounded.

15. The power-on reset circuit of claim 14, further comprising a reverser, wherein the reverser comprises an input terminal and an output terminal; the input terminal of the reverser is connected to the junction of the collector of the second transistor and a first terminal of the fifth resistor; the output terminal of the reverser is connected to the reset terminal.
